(19) United States
(12) Patent Application Publication
(10) Pub. No.: US 2008/0012654 A1
(43) Pub. Date: Jan. 17, 2008

(54) LINEARIZED VARIABLE-CAPACITANCE MODULE AND LC RESONANCE CIRCUIT USING THE SAME

(76) Inventors: Seon Ho HAN, Daejeon (KR); Cheon Soo KIM, Daejeon (KR)

Correspondence Address: LADAS & PARRY LLP, 224 SOUTH MICHIGAN AVENUE, SUITE 1600, CHICAGO, IL, 60604, US

(21) Appl. No.: 11/768,416

(22) Filed: Jun. 26, 2007

(30) Foreign Application Priority Data
Jul. 14, 2006 (KR) 10-2006-0066409

(51) Int. Cl. H03B 5/08

(52) U.S. Cl. 331/167; 331/177 V

(57) ABSTRACT

Provided are a linearized variable-capacitance module for a voltage-controlled oscillator (VCO) and an LC resonance circuit using the same. The VCO is a circuit for outputting a certain frequency in response to an input control signal (voltage or current). The VCO includes an inductor, a variable capacitor (or a varactor), and an active device for compensating for loss of energy caused by the inductor and varactor. The frequency of the VCO is varied by changing inductance or capacitance. In general, the VCO includes a variable-capacitance device (i.e., the varactor) so that the frequency of the VCO may be varies by changing the capacitance via a control voltage. In most cases, the frequency of the VCO varies nonlinearly with respect to the control voltage. The nonlinear variation in the frequency of the VCO results in a great variation in a VCO gain within a certain control voltage range. When a phase locked loop (PLL) includes the VCO, the variation in the VCO gain leads to a variation in the entire loop gain, thus causing a variation in output phase noise. To solve this problem, a varactor designed to have a capacitance that varies linearly with a control voltage is provided so that a VCO gain can be held constant. The variable-capacitance module includes a plurality of variable-capacitance devices with respectively different linear variation regions on an application voltage axis. Also, the variable-capacitance devices are coupled in common and receive a control voltage at one end while each receiving a different fixed voltage at the other end.

### CROSS-REFERENCE TO RELATED APPLICATION

This application claims priority to and the benefit of Korean Patent Application No. 2006-0066409, filed Jul. 14, 2006, the disclosure of which is incorporated herein by reference in its entirety.

### BACKGROUND

1. Field of the Invention

The present invention relates to a variable capacitor (hereinafter, varactor) applicable to a voltage-controlled oscillator (VCO), which generates a signal at a frequency that varies linearly with a control voltage.

2. Discussion of Related Art

FIG. 1 is a block diagram of a conventional voltage-controlled oscillator (VCO). The VCO is a circuit for generating an output signal at a specific frequency in response to a control signal. The VCO includes an inductor-capacitor (LC) resonance circuit, which is comprised of an inductor and a capacitor, and an active device for compensating for undesirable energy loss caused by the LC resonance circuit. In the LC resonance circuit, the frequency is varied by changing inductance (L) or, in most cases, capacitance (C).

FIG. 2 is a graph showing characteristics of a conventional varactor. Specifically, FIG. 2 is a graph of capacitance versus control voltage in the conventional varactor. As can be seen from FIG. 2, the capacitance of the varactor varies nonlinearly with respect to the control voltage. Thus, when this conventional varactor is applied to an oscillator, the gain of the oscillator, which is defined as change in frequency per change in control voltage (i.e., K_{VCO}=Δf_{VCO}/ΔV), varies greatly over the entire control voltage range.

The VCO is located in a negative loop of a phase locked loop (PLL) in order to output a signal at a precise frequency. In this case, variation in the gain of the VCO leads to variation in the characteristic of the entire negative loop. That is, output phase noise is changed by varying the gain of the entire negative loop. FIG. 3 is a circuit diagram of a single-ended LC resonance circuit of a conventional resonator, and FIG. 4 is a circuit diagram of a differential-ended LC resonance circuit of a conventional resonator. As can be seen from FIGS. 3 and 4, one node of a varactor is coupled to an oscillation node, and the other node of the varactor is coupled to a control voltage for varying capacitance. In this case, since the capacitance varies nonlinearly with respect to control voltage as described above, it is impossible to ensure precise control of oscillation frequency.

In order to solve this problem, a VCO may include a plurality of varactors for different control voltage ranges that can be switched between according to the control voltage. However, in this case, the VCO may suffer from disturbance due to switching operations and needs complicated control circuits for the switching operations.

### SUMMARY OF THE INVENTION

The present invention is directed to a variable-capacitance module having a linear frequency variance characteristic, and an LC resonance circuit using the same.

The present invention is also directed to a variable-capacitance module capable of outputting a linear frequency variance characteristic without switching a varactor, and an LC resonance circuit using the same.

One aspect of the present invention provides a variable-capacitance module including a plurality of variable-capacitance devices having different linear variation regions on a voltage axis. Herein, the variable-capacitance devices are coupled in common and receive a control voltage at one end while each receiving a different fixed voltage at the other end.

Another aspect of the present invention provides a single-ended LC resonance circuit including an inductor providing a resonance inductance; and a variable-capacitance module having one end coupled to one end of the inductor and the other end coupled to the other end of the inductor. Herein, the variable-capacitance module includes a plurality of variable-capacitance devices coupled in common and receiving a control voltage at one end while each receiving a different fixed voltage at the other end, respectively.

Yet another aspect of the present invention provides a differential-ended LC resonance circuit including an inductor providing a resonance inductance; a first variable-capacitance module having one end coupled to one end of the inductor; and a second variable-capacitance module having one end coupled to the other end of the inductor and the other end coupled to the other end of the first variable-capacitance module and to which a control voltage is applied. Herein, each of the first and second variable-capacitance modules includes a plurality of variable-capacitance devices respectively coupled in common and receiving a control voltage at one end while each receiving a different fixed voltage at the other end.

### BRIEF DESCRIPTION OF THE DRAWINGS

The above and other objects, features and advantages of the present invention will become more apparent to those of ordinary skill in the art by describing in detail exemplary embodiments thereof with reference to the attached drawings in which:

FIG. 1 is a block diagram of a conventional voltage-controlled oscillator (VCO);

FIG. 2 is a graph showing characteristics of a conventional varactor;

FIG. 3 is a circuit diagram of a single-ended LC resonance circuit of a conventional resonator;

FIG. 4 is a circuit diagram of a differential-ended LC resonance circuit of a conventional resonator;

FIG. 5 is a conceptual diagram of a linearized variable-capacitance module including n varactors according to an exemplary embodiment of the present invention;

FIG. 6 is a graph showing characteristics of the linearized variable-capacitance module of FIG. 5;

FIG. 7 is a conceptual diagram of a linearized variable-capacitance module including 3 varactors according to another exemplary embodiment of the present invention;

FIG. 8 is a graph showing characteristics of the linearized variable-capacitance module of FIG. 7;

FIG. 9 is a circuit diagram of a single-ended LC resonance circuit of a resonator using the linearized variable-capacitance module of FIG. 7;

FIG. 10 is a circuit diagram of a differential-ended LC resonance circuit of a resonator using the linearized variable-capacitance module of FIG. 7;

FIG. 11 is a conceptual diagram of a linearized variable-capacitance module including n varactors and n switched capacitor blocks according to yet another exemplary embodiment of the present invention;

FIG. 12 is a graph showing characteristics of the linearized variable-capacitance module of FIG. 11;

FIG. 13 is a conceptual diagram of a linearized variable-capacitance module including 3 varactors and 3 switched capacitor blocks according to yet another exemplary embodiment of the present invention;

FIG. 14 is a graph showing characteristics of the linearized variable-capacitance module of FIG. 13;

FIG. 15 is a circuit diagram of a single-ended LC resonance circuit of a resonator using the linearized variable-capacitance module of FIG. 13;

FIG. 16 is a circuit diagram of a differential-ended LC resonance circuit of a resonator using the linearized variable-capacitance module of FIG. 13;

FIG. 17 is a conceptual diagram of a linearized variable-capacitance module including n switched varactors according to yet another exemplary embodiment of the present invention; and

FIG. 18 is a circuit diagram of a differential-ended LC resonance circuit of a resonator using the linearized variable-capacitance module of FIG. 17.

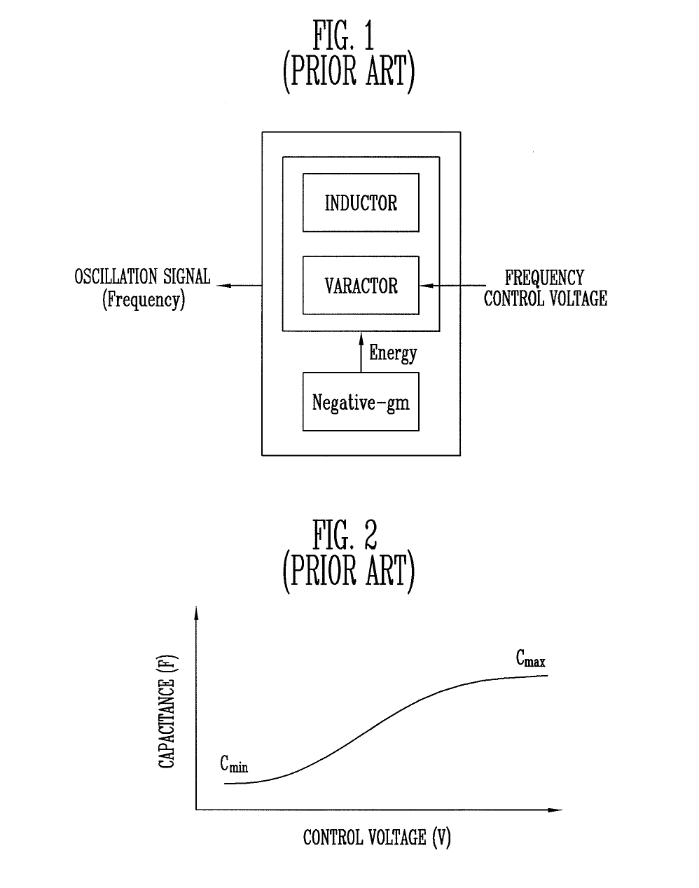

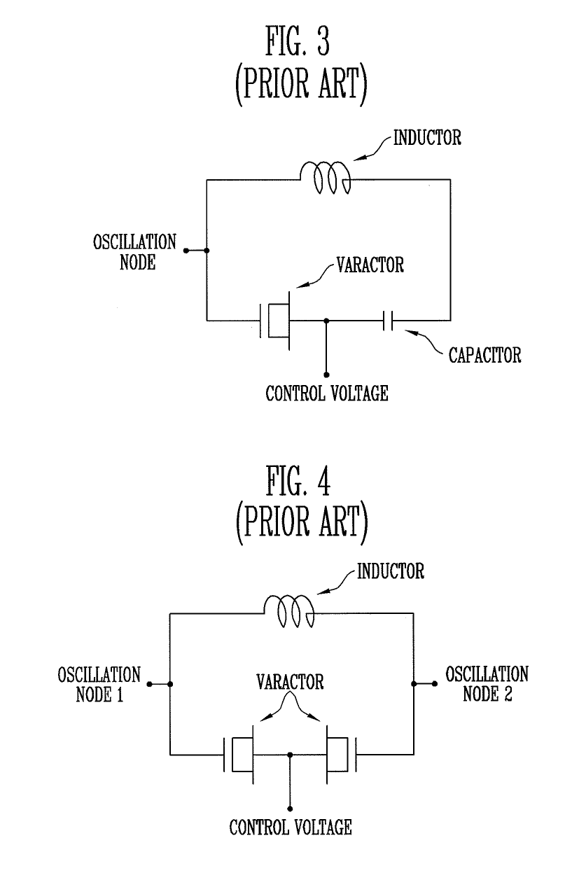

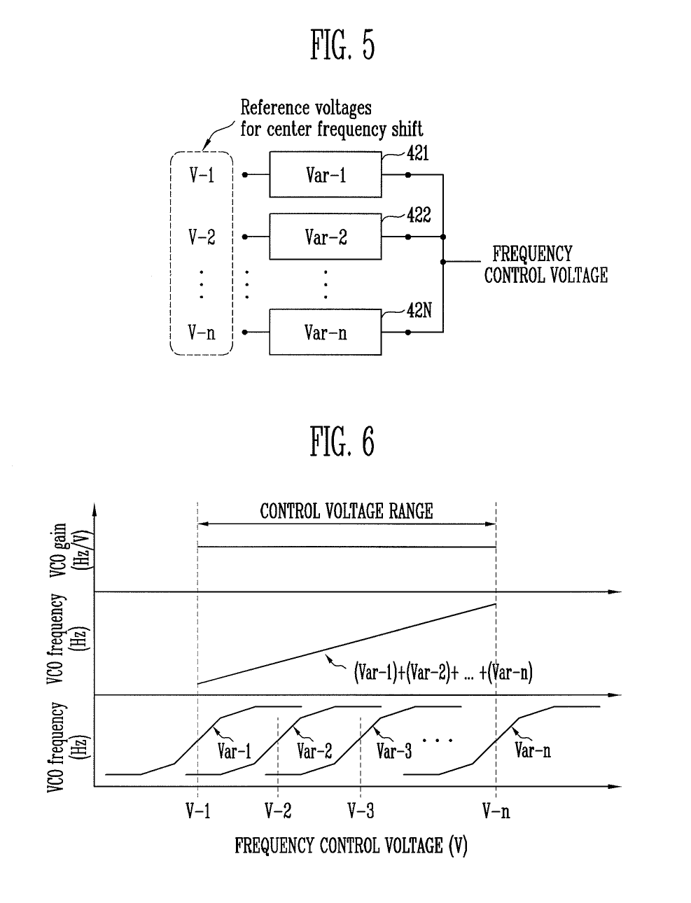

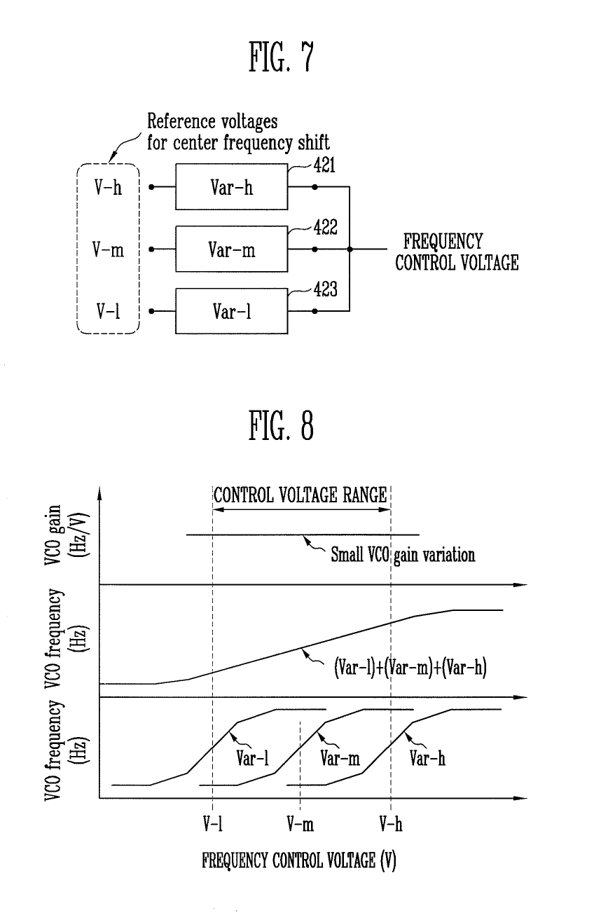

### DETAILED DESCRIPTION OF EXEMPLARY EMBODIMENTS

Hereinafter, exemplary embodiments of the present invention will be described in detail. However, the present invention is not limited to the exemplary embodiments disclosed below and can be implemented in various forms. Therefore, the present exemplary embodiments are provided for complete disclosure of the present invention and to fully convey the scope of the present invention to those of ordinary skill in the art.

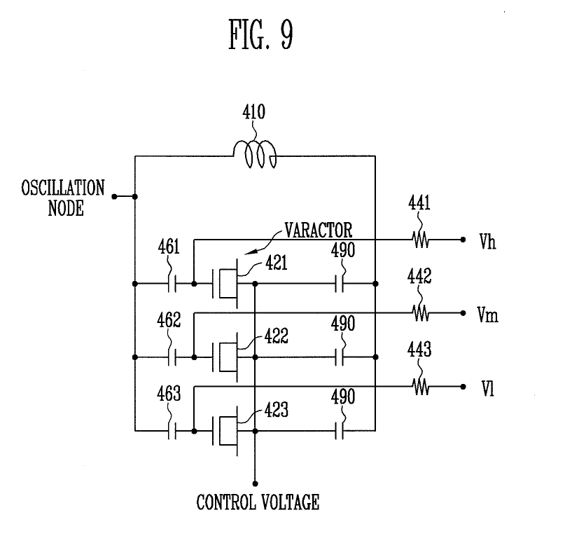

FIG. 5 is a conceptual diagram of a linearized variable-capacitance module including n varactors according to an exemplary embodiment of the present invention, and FIG. 6 is a graph of frequency versus control voltage in a voltage-controlled oscillator (VCO) using the linearized variable-capacitance module of FIG. 5.

As can be seen from the lowermost graph of FIG. 6, one varactor is characterized such that the maximum capacitance Var-n and the minimum capacitance Var-1 are sufficiently within the entire variation range of control voltage. In this case, as shown in FIG. 5, a variable-capacitance module includes a plurality of varactors coupled in common and receiving a control voltage at one end while each receiving a different fixed voltage V-1 to V-n at the other end, in order that the entire variable-capacitance module may have a linear frequency-control voltage characteristic.

The fixed voltages V-1 to V-n allow the respective variation central points of varactors 421, 422, . . . , and 42N to shift to a specific voltage point with respect to the control voltage, so that the respective capacitances Var-1, Var-2, . . . , and Var-n of the varactors 421, 422, . . . , and 42N are aligned within the control voltage range, as can be seen from the lowermost graph of FIG. 6. In other words, once the capacitance Var-1 of the leftmost first varactor 421 having one side to which a voltage V-1 is applied varies due to the control voltage and then reaches the maximum value, the capacitance Var-2 of the second varactor 422 having one side to which a voltage V-2 is applied subsequently varies due to the control voltage. In this case, the voltages V-1 and V-2 are determined such that the capacitances of two varactors 421 and 422 with similar characteristics vary linearly due to the control voltage.

Therefore, the entire capacitance of the variable-capacitance module, which is a result obtained by adding all the variable capacitances Var-1, Var-2, . . . , and Var-n of the varactors 421, 422, . . . , and 42N, may have a linear variation as shown in the intermediate graph of FIG. 6 within the control voltage range shown in the uppermost graph of FIG. 6. In this case, when designing a real VCO, the respective fixed voltages V-1 to V-n should be isolated and applied using isolation capacitors such that an alternating current (AC) signal can swing at a node.

As a result, a gain of the VCO as shown in the uppermost graph of FIG. 6 approximates a specific constant. In the configuration of FIG. 5, the fixed voltages V-1 to V-n, which cause a voltage offset among the varactors 421, 422, . . . , and 42N, are arbitrarily selected such that the overall capacitance varies linearly, and the capacitances Var-1, Var-2, . . . , and Var-n of the varactors 421, 422, . . . , and 42N also should be selected such that the overall capacitance varies linearly. To this end, all the varactors 421, 422, . . . , and 42N may be within the same capacitance range or within differential capacitance ranges.

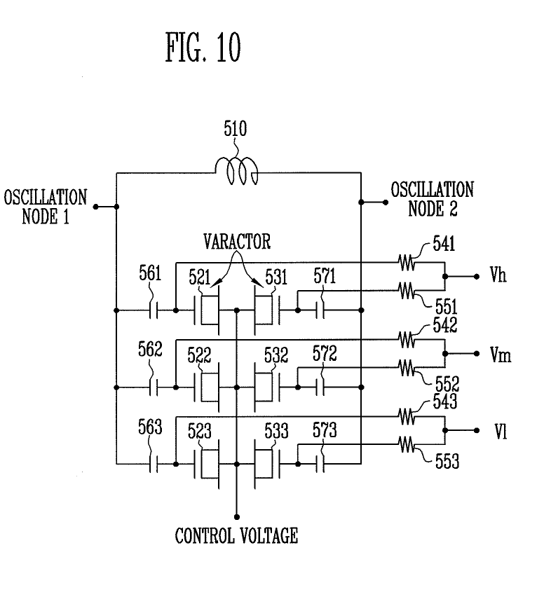

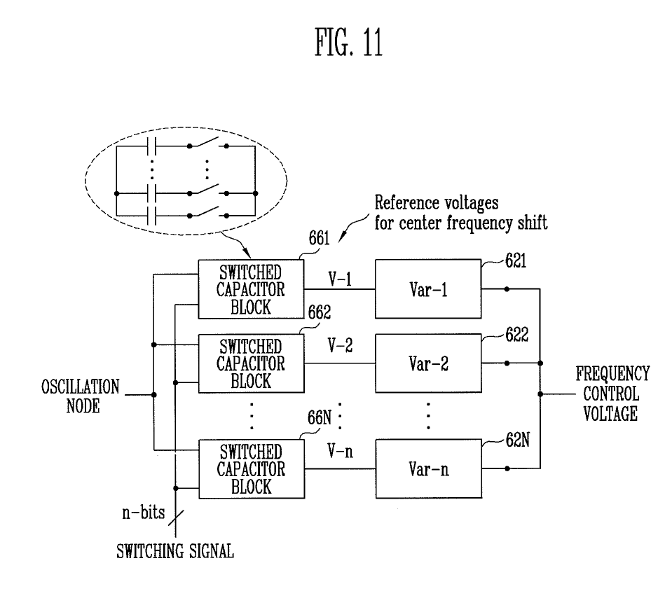

FIG. 7 is a conceptual diagram of a linearized variable-capacitance module including 3 varactors according to another exemplary embodiment of the present invention, and FIG. 8 is a graph showing characteristics of the linearized variable-capacitance module of FIG. 7. The variable-capacitance module of FIG. 7 is the same as that of FIG. 5 except that the variable-capacitance module includes 3 varactors 421, 422, and 423. When a phase locked loop (PLL) is designed and the entire block is designed using a single power supply, a real variable-capacitance module has a variation in power supply voltage similar to the varactor 422 corresponding to an intermediate region among the three varactors 421, 422, and 423 shown in FIG. 8. In an integrated circuit (IC), a junction varactor or a MOS varactor may be typically used as each of the varactors 421, 422, and 423. As described above, the variable-capacitance module has the construction shown in FIG. 7 so that a VCO can output a signal at a frequency that varies linearly within the entire control voltage range. The entire control voltage range shown in the uppermost graph of FIG. 8 covers at least all control voltage regions of the respective varactors 421, 422, and 423.

Like in the previous exemplary embodiment, the entire variable-capacitance module is comprised of three varactors 421, 422, and 423 of which one end is commonly coupled to a control voltage and of which the other end is coupled to fixed voltages V-h, V-m, and V-1, respectively, to have a voltage offset, so that the VCO shows a linear frequency variation in the entire control voltage range as shown in FIG. 8. In the present exemplary embodiment, since variable-capacitance devices are varactors, each end to which a control voltage is applied corresponds to anodes of the varactors 421, 422, and 423, while each end to which the respective fixed voltages V-h, V-m, and V-1 are applied corresponds to cathodes thereof. As a result, a constant VCO gain characteristic can be obtained as shown in FIG. 8.

FIGS. 9 and 10 show examples of an LC resonance circuits. Specifically, FIG. 9 is a circuit diagram of a single-ended LC resonance circuit of a resonator using the linearized variable-capacitance module of FIG. 7, while FIG. 10 is a circuit diagram of a differential-ended LC resonance circuit of a resonator using the linearized variable-capacitance module of FIG. 7. In FIGS. 9 and 10, each LC resonance circuit includes an inductor, the variable-capacitance module shown in FIG. 7, and a direct current (DC)-blocking coupling capacitor, and the variable-capacitance module includes 3 varactors 421, 422, and 423 in order to obtain a linear frequency variation with respect to a control voltage.

As can be seen from FIGS. 9 and 10, cathodes of the varactors 421, 422, and 423 are isolated from one another and anodes thereof are coupled to one another. In this state, a control voltage is applied to the anodes of the varactors 421, 422, and 423, while respective fixed voltages are applied to the cathodes thereof.

In order to prevent application of the control voltage to an LC oscillation path, first coupling capacitors 490 are located between the anodes of the varactors 421, 422, and 423 and one end of the inductor 410, and second coupling capacitors 461, 462, and 463 are located between the cathodes of the varactors 421, 422, and 423 and the other end of the inductor 410, respectively. Since the anodes of the varactors 421, 422, and 423 are coupled to one another, the first coupling capacitors 490 may be embodied by one capacitor. However, since the cathodes of the varactors 421, 422, and 423 are isolated from one another, the second coupling capacitors 461, 462, and 463 should be embodied by three capacitors as shown in FIG. 9.

Meanwhile, in order to prevent an oscillated AC signal from passing through a line for applying the fixed voltage, AC-blocking resistors 441, 442, and 443 may be located on lines for applying the fixed voltages, respectively, as shown in FIG. 9. The AC-blocking resistors 441, 442, and 443 may be replaced by other devices, such as inductors, which allow application of DC signals and block application of AC signals. Although not shown in the drawings, an AC-blocking resistor or inductor may be further located on a line for applying the control voltage in order to prevent the oscillated AC signal from passing through the line for applying the control voltage.

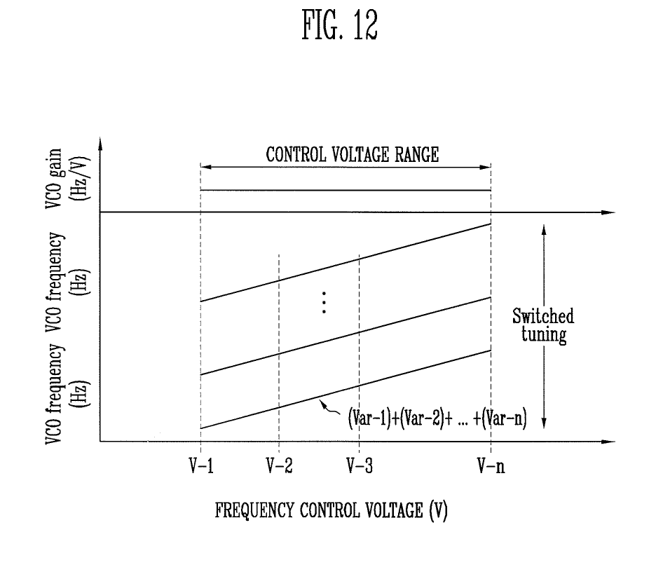

FIG. 11 is a conceptual diagram of a linearized variable-capacitance module including n varactors and n switched capacitor blocks according to yet another exemplary embodiment of the present invention, and FIG. 12 is a graph showing characteristics of the linearized variable-capacitance module of FIG. 11. Specifically, switched capacitor tuning is applied to the variable-capacitance module of FIG. 11 so that a frequency can vary within a larger range. Unlike conventional switched capacitor tuning, DC coupling capacitors located between varactors and oscillation nodes are embodied by switched capacitor blocks 661, 662, . . . , and 66N.

A variation in capacitance caused by use of a switched capacitor block, which results in a great variation in an oscillation frequency range, is referred to as “switch tuning,” and a frequency range defined by the switch tuning is referred to as a “frequency band.” In other words, a frequency band is changed due to the switch tuning of the switched capacitor block.

When a frequency becomes low due to the switching of the switched capacitor block, the variation range of a variable-capacitance device due to an analog voltage should increase more so that the same VCO gain can be obtained even at a low frequency. Therefore, when the switch tuning is embodied using the coupling capacitor block as shown in FIG. 11, the switched capacitor blocks 661, 662, . . . , and 66N and varactors 621, 622, . . . , and 62N are coupled in series, the entire variation range due to the varactors 621, 622, . . . , and 62N is automatically changed. Specifically, when the capacitance of the switched capacitor blocks 661, 662, . . . , and 66N is great, the entire variation range due to the varactors 621, 622, . . . , and 62N increases; on the other hand, when the capacitance of the switched capacitor blocks 661, 662, . . . , and 66N is small, the entire variation range due to the varactors 621, 622, . . . , and 62N decreases. As a result, the construction shown in FIG. 11 enables switched frequency tuning while reducing a variation in the VCO gain.

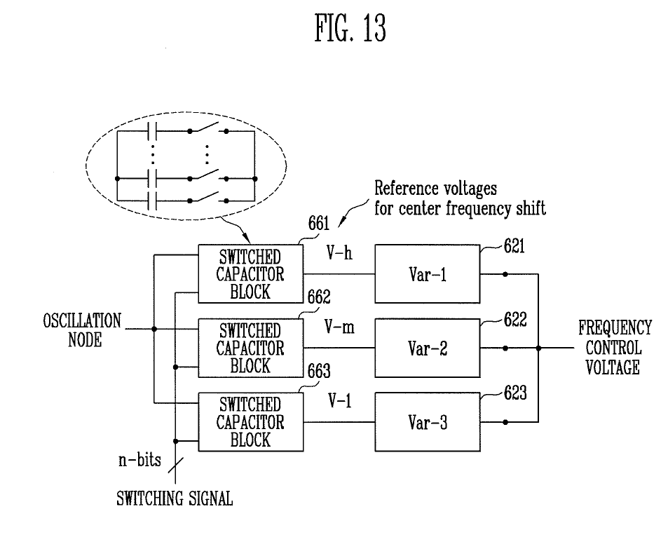

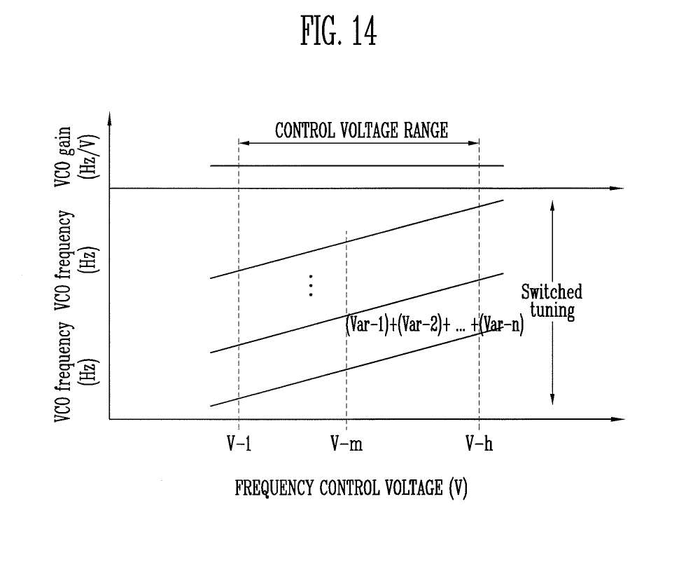

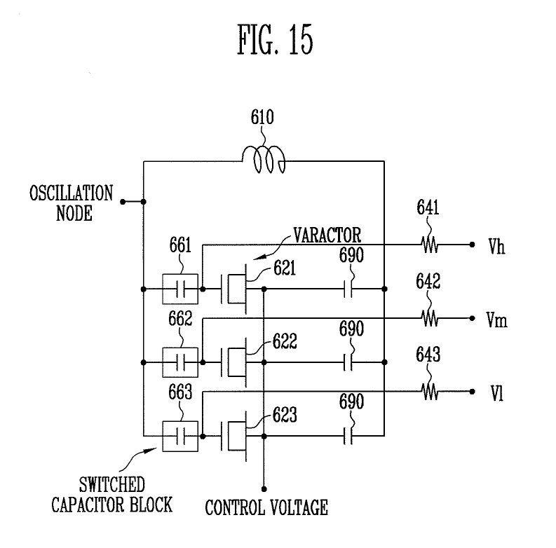

FIG. 13 is a conceptual diagram of a linearized variable-capacitance module including 3 varactors and 3 switched capacitor blocks according to yet another exemplary embodiment of the present invention, and FIG. 14 is a graph showing characteristics of the linearized variable-capacitance module of FIG. 13. In FIG. 13, three varactors 621, 622, and 623 are coupled to switched capacitor blocks 661, 662, and 663, respectively. The variable-capacitance module shown in FIG. 13 is a simple type with high feasibility. Since the variable-capacitance module shown in FIG. 13 is analogous to the variable-capacitance module described with reference to FIGS. 11 and 12, a detailed description thereof will be omitted here.

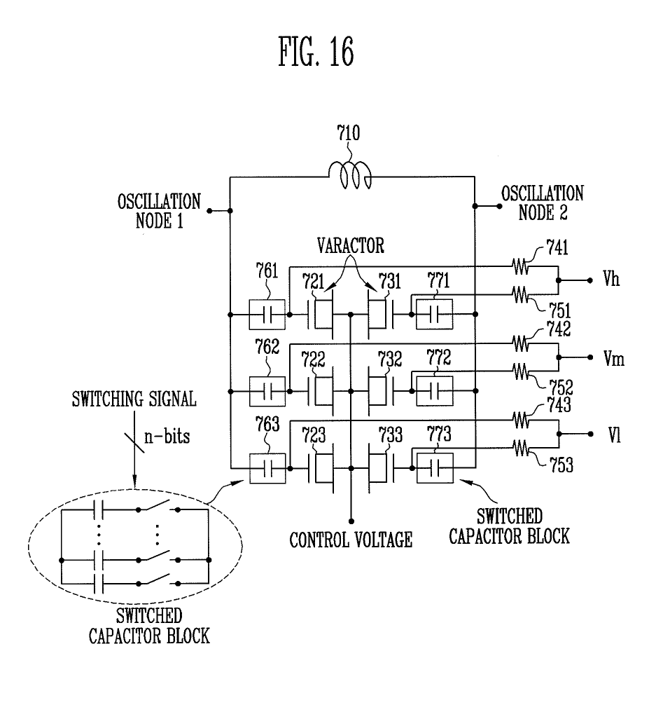

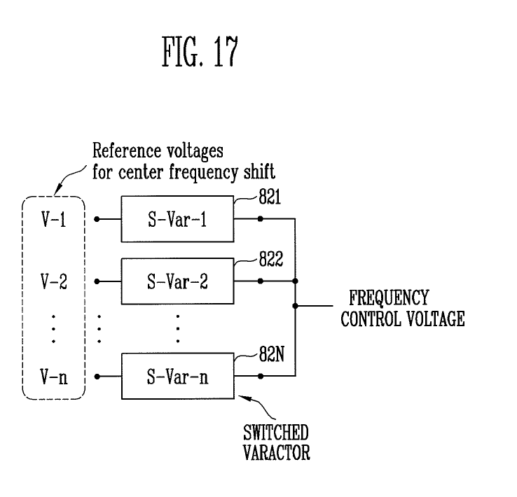

FIG. 15 is a circuit diagram of a single-ended LC resonance circuit of a resonator using the linearized variable-capacitance module of FIG. 13, and FIG. 16 is a circuit diagram of a differential-ended LC resonance circuit of a resonator using the linearized variable-capacitance module of FIG. 13.

The variable-capacitance module shown in FIG. 15 is the same as that of FIG. 9 except that the second coupling capacitors 461, 462, and 463 are replaced by switched capacitor blocks 661, 662, and 663, respectively. Although not shown in the drawings, the variable-capacitance module shown in FIG. 15 may be constructed by replacing the first coupling capacitor 490 of FIG. 9 by a switched capacitor block. In the latter case, since the variable-capacitance module may include only one switched capacitor block, the fabrication cost and an occupied area can be lessened, whereas a switching operation on one end of a varactor to which a control voltage is applied may deteriorate the stability of an oscillation operation of a VCO. Therefore, in the latter case, the variable-capacitance module should include three switched capacitor blocks considering the stability of the oscillation operation of the VCO.

The variable-capacitance module shown in FIG. 16 is the same as that of FIG. 10 except that first coupling capacitors 571, 572, and 573 are replaced by first switched capacitor blocks 771, 772, and 773, respectively, and second coupling capacitors 561, 562, and 563 are replaced by second switched capacitor blocks 761, 762, and 763, respectively.

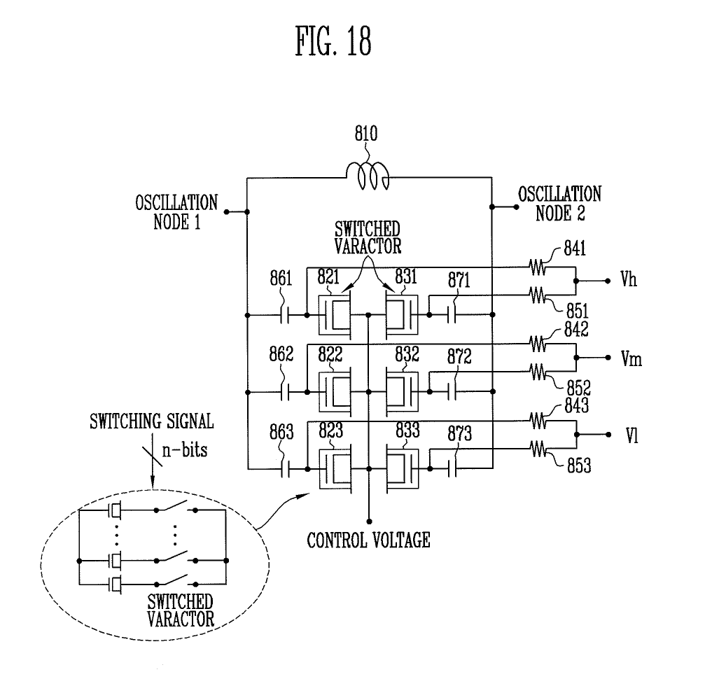

FIG. 17 is a conceptual diagram of a linearized variable-capacitance module including n switched varactors according to yet another exemplary embodiment of the present invention. Specifically, another method for switched capacitor tuning is applied so that a frequency can vary within a larger range. In the present exemplary embodiment, a variable-capacitance device is embodied by a switched variable-capacitance block in order to control the switching of the variable-capacitance device. On switching the variable-capacitance device, when a frequency becomes high and low, a variation in frequency band due to switched tuning and a variation in variable capacitance due to a control voltage are caused by the switched variable-capacitance block, and thus a VCO gain is kept constant.

FIG. 18 is a circuit diagram of a differential-ended LC resonance circuit of a resonator using the linearized variable-capacitance module of FIG. 17. Although only the differential-ended LC resonance circuit is illustrated, it would be apparent that the variable-capacitance module of FIG. 17 may be applied likewise to a single-ended LC resonance circuit. Since both the differential-ended and single-ended LC resonance circuits are analogous to circuits explained above, a detailed description thereof will be omitted here.

A variable-capacitance module according to the present invention is characterized by a linear frequency variation in a control voltage range for a variation in the frequency of a VCO, unlike conventional designs for varactors, so that a constant VCO gain can be obtained.

Also, a conventional varactor leads a VCO gain to vary within a large range. When the variable-capacitance module according to the present invention is designed to have the same gain as the maximum gain of a VCO using the conventional varactor, the variable-capacitance module according to the present invention can have an even greater frequency variation range than the conventional varactor.

Further, when the variable-capacitance module according to the present invention is designed to have the same gain as the average gain of a VCO, the variable-capacitance module according to the present invention can obtain a constantly low gain in the entire range while having a frequency variation range similar to that of a conventional varactor. A VCO with a relatively low gain is advantageous in lowering output phase noise of a PLL.

Most importantly, a constant VCO gain can be achieved within the entire control voltage range. A conventional varactor can neither increase a frequency variation range because of a large variation in VCO gain nor obtain a constant VCO characteristic owing to a great change in output phase noise. In contrast, the variable-capacitance module according to the present invention can obtain a constant VCO gain within the entire control voltage range so that a frequency variation range can be increased and noise can be reduced.

Considering that a VCO is an essential block for a PLL, which is broadly used in various circuits, such as data recoveries, clock recoveries, RF receivers, RF transmitters, and frequency synthesizers, it is important that the present invention should make a variation in VCO gain, which is regarded as a serious drawback to the VCO, constant. Therefore, by applying the present invention to the above-described circuits, the performance of the circuits can be improved clearly and simply, thus resulting in great marketability and economical efficiency.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A variable-capacitance module comprising a plurality of variable-capacitance devices having different linear variation regions on a voltage axis,
wherein the variable-capacitance devices are coupled in common and receive a control voltage at one end while each receiving a different fixed voltage at the other end.

2. The variable-capacitance module according to claim 1, wherein each of the variable-capacitance devices is a varactor.

3. The variable-capacitance module according to claim 2, wherein the control voltage is applied to anodes of the varactors, and different fixed voltages are applied to cathodes of the varactors, respectively.

4. The variable-capacitance module according to claim 1, wherein the fixed voltages are determined such that the parallel-connected sum of the capacitances of the variable-capacitance devices varies linearly with the control voltage in a region including all the linear variation regions of the variable-capacitance devices.

5. The variable-capacitance module according to claim 1, wherein the capacitances of the variable-capacitance devices are determined such that the parallel-connected sum of the capacitances of the variable-capacitance devices varies linearly with the control voltage in a region including all the linear variation regions of the variable-capacitance devices.

6. The variable-capacitance module according to claim 1, wherein each of the fixed voltages is applied through an alternating current (AC)-blocking device.

7. The variable-capacitance module according to claim 1, wherein each of the variable-capacitance device comprises a plurality of parallel-connected varactors that are disconnected from and connected to one another in response to each bit of a switching signal.

8. The variable-capacitance module according to claim 1, further comprising:
a first coupling capacitor located between a node to which the control voltage is applied and a first external connection terminal; and
a second coupling capacitor located between a node to which each of the fixed voltages is applied and a second external connection terminal.

9. An LC resonance circuit comprising:
an inductor providing resonance inductance; and
a variable-capacitance module having one end coupled to one end of the inductor and the other end coupled to the other end of the inductor,
wherein the variable-capacitance module comprises a plurality of variable-capacitance devices coupled in common and receiving a control voltage at one end while each receiving a different fixed voltage at the other end.

10. The LC resonance circuit according to claim 9, further comprising:
a first coupling capacitor for coupling the resonance inductor to one end of each of the variable-capacitance devices of the variable-capacitance module; and
a second coupling capacitor for coupling the resonance inductor to the other end of each of the variable-capacitance devices of the variable-capacitance module.

11. The LC resonance circuit according to claim 10, wherein the first coupling capacitor comprises a plurality of parallel-connected capacitors that are disconnected from and connected to one another in response to each bit of a switching signal.

12. The LC resonance circuit according to claim 10, wherein the second coupling capacitor comprises a plurality of parallel-connected capacitors that are disconnected from and connected to one another in response to each bit of a switching signal.

13. An LC resonance circuit comprising:
an inductor providing resonance inductance;
a first variable-capacitance module having one end coupled to one end of the inductor; and
a second variable-capacitance module having one end coupled to the other end of the inductor and the other end coupled to the other end of the first variable-capacitance module to receive a control voltage,
wherein each of the first and second variable-capacitance modules comprises a plurality of variable-capacitance devices coupled in common and receiving a control voltage at one end while each receiving a different fixed voltage at the other end.

14. The LC resonance circuit according to claim 13, further comprising:
a first coupling capacitor for coupling the resonance inductor to the first variable-capacitance module; and
a second coupling capacitor for coupling the resonance inductor to the second variable-capacitance module.

15. The LC resonance circuit according to claim 14, wherein the first coupling capacitor comprises a plurality of parallel-connected capacitors that are disconnected from and connected to one another in response to each bit of a switching signal.

16. The LC resonance circuit according to claim 14, wherein the second coupling capacitor comprises a plurality of parallel-connected capacitors that are disconnected from and connected to one another in response to each bit of a switching signal.
